(19) United States
(12) Patent Application Publication
(10) Pub. No.: US 2015/0287906 A1
(43) Pub. Date: Oct. 8, 2015

(54) POLYMER BLENDS OF ELECTROSTRICTIVE TERPOLYMER WITH OTHER POLYMERS

(71) Applicant: The Penn State Research Foundation, University Park, PA (US)

(72) Inventors: Qiming ZHANG, University Park, PA (US); Minren LIN, University Park, PA (US); Sheng LIU, University Park, PA (US); Lee J. GORNY, University Park, PA (US)

(21) Appl. No.: 14/692,935

(22) Filed: Apr. 22, 2015

Related U.S. Application Data
(62) Division of application No. 13/384,196, filed on Apr. 2, 2012.
(60) Provisional application No. 61/225,722, filed on Jul. 15, 2009.

(51) Int. Cl. H01L 41/193; B32B 27/30

(52) U.S. Cl. CPC H01L 41/193; B32B 27/304; B32B 2457/00

(57) ABSTRACT

Polymer blends having improved electromechanical responses and mechanical properties for use in electromechanical application are disclosed. In particular, polymer blend including at least one electrostrictive terpolymer, e.g., poly(vinylidene fluoride-trifluoroethylene-chlorofluoroethylene) (P(VDF-TrFE-CFE)) or a derivative thereof, and at least one fluoropolymer, e.g., PVDF or derivative thereof such as PVD-TrFE are disclosed. The polymer blends advantageously have a transverse strain, i.e., a strain perpendicular to the applied electric field direction, that is about 1.5% or higher (as measured at 100 MV/m) while also having an elastic modulus of no less than about 400 MPa (as measured at 30° C. and 1 Hz by dynamic mechanical analyzer).

### CROSS REFERENCE TO RELATED APPLICATIONS

This application claims the benefit of U.S. Provisional Application No. 61/225,722, filed 15 Jul. 2009, the entire disclosure of which is hereby incorporated by reference herein.

### STATEMENT REGARDING FEDERALLY SPONSORED RESEARCH

This invention was made with government support under Grant No. 5R01EY018387-01 and 5R01EY018387-02, awarded by the National Institutes of Health. The Government has certain rights in the invention.

### TECHNICAL FIELD

The present invention relates to multifunctional active polymeric blends having improved electromechanical properties and in particular polymer blends exhibiting elevated electrical field induced strain level, and elevated elastic energy density and elastic modulus. The materials can be used in electromechanical devices such as actuators and sensors which convert electrical energy into mechanical energy or convert mechanical energy into electrical energy. The electromechanical actuator devices can be used as, but not limited to, diaphragms for fluid pumps, solid state actuators for auto-focusing of camera lens, for precision position control, and for micro-steering of medical catheters.

### BACKGROUND

In recent years, several fluoropolymers, especially poly(vinylidene fluoride-trifluoroethylene-chlorofluoroethylene) (P(VDF-TrFE-CFE)), poly(vinylidene fluoride-trifluoroethylene-chlorotrifluoroethylene) (P(VDF-TrFE-CTFE)) and other related P(VDF-TrFE) based electrostrictive terpolymers, have been developed which exhibit very high strain under electrical field (for example, 5% strain under 150 MV/m). Examples of such fluoropolymers are described in U.S. Pat. No. 6,787,238 which is incorporated herein by reference. Furthermore, these terpolymers also show high elastic energy density, e.g., higher than 0.5 J/cm³.

However, the high electromechanical properties of terpolymers are generally reported from the thickness strain, which is the strain along the direction of the applied electrical field (see FIG. 1, where thickness strain S₃ is parallel to the direction of the applied electric field). For many practical applications the transverse strain, which is the strain in the direction perpendicular to the applied field direction, is the strain that is more applicable and used. Hence, it is highly desirable to have polymers with high electromechanical responses in perpendicular to the applied electrical field direction (the transverse strains, S₁ and S₂ in FIG. 1). As shown in FIG. 2, a transverse strain S₁ can reach 4.8% under 140 MV/m for a P(VDF-TrFE-CFE) terpolymer uniaxially stretched where S₁ is along the film stretching direction.

Further, many terpolymers with high electromechanical properties have relatively low elastic modulus. Efforts to improve the modulus of these materials can in turn adversely affect the high electromechanical properties. Accordingly, a need exists to provide polymeric materials that have high electromechanical properties and high elastic modulus, particular for polymeric materials used in electromechanical devices.

### SUMMARY OF THE DISCLOSURE

The present disclosure relates to polymer materials in which a high strain polymer is blended with another polymer to increase the overall elastic modulus of the material without materially adversely affecting the electromechanical strain of the polymers. Preferably, the blend can still exhibit the same or similar levels of transverse strain response as the neat high strain polymer.

These and other advantages are satisfied, at least in part, by a polymer blend comprising at least one electrostrictive terpolymer, e.g., poly(vinylidene fluoride-trifluoroethylene-chlorofluoroethylene) (P(VDF-TrFE-CFE)) or a derivative thereof, and at least one fluoropolymer, e.g., PVDF or derivative thereof such as PVD-TrFE. Advantageously the polymer blend has a transverse strain, i.e., a strain perpendicular to the applied electric field, that is about 1.5% or higher, e.g. 2% or higher, (as measured at 100 MV/m) while also having an elastic modulus of no less than about 400 MPa, e.g., no less than about 500 MPa, (as measured at 30° C. or lower, e.g. at about 25° C., and 1 Hz by dynamic mechanical analyzer).

The electrostrictive terpolymer can be selected from the group consisting of: polyvinylidene fluoride-trifluoroethylene-chlorofluoroethylene (P(VDF-TrFE-CFE)), polyvinylidene fluoride-trifluoroethylene-chlorodifluoroethylene (P(VDF-TrFE-CDFE)), polyvinylidene fluoride-trifluoroethylene-chlorotrifluoroethylene (P(VDF-TrFE-CTFE)), polyvinylidene fluoride-trifluoroethylene-hexafluoropropylene (P(VDF-TrFE-HFP)), polyvinylidene fluoride-trifluoroethylene-tetrafluoroethylene (P(VDF-TrFE-TFE)), polyvinylidene fluoride-tetrafluoroethylene-chlorofluoroethylene (P(VDF-TFE-CFE)), polyvinylidene fluoride-tetrafluoroethylene-chlorodifluoroethylene (P(VDF-TFE-CDFE)), polyvinylidene fluoride-tetrafluoroethylene-chlorotrifluoroethylene (P((VDF-TFE-CTFE)), polyvinylidene fluoride-tetrafluoroethylene-hexafluoropropylene (P(VDF-TFE-HFP)). Advantageously the polymer blend has a transverse strain that is no less than about 1.5%, e.g., no less than about 2%, (as measured at 100 MV/m) while also having an elastic modulus of no less than about 400 MPa, e.g., no less than about 500 MPa (as measured at 30° C. and 1 Hz by dynamic mechanical analyzer).

In one embodiment of the present disclosure, the general chemical formula of the electrostrictive terpolymer is P(VDFₓ-2nd monomer_{y}-3rd monomer_{1-x-y}) where the 2nd monomer is selected from TrFE, TFE, and the 3rd monomer is selected from CFE, CDFE, CTFE, HFP. The variables x and y are not limited but can be from 0.50 to 0.75 for x and 0.2 to 0.4 for y. The fluoropolymer can be selected from the group consisting of P(VDF_{z}-CTFE_{1-z}), P(VDF_{z}-CFE_{1-z}), P(VDF_{z}-HFP_{1-z}), P(VDF_{z}-CDFE_{1-z}), P(VDF-TrFE_{1-z}), P(VDF_{z}-TFE_{1-z}), P(VF_{z}-CTFE_{1-z}), [VF=vinyl fluoride] P(VF_{z}-CFE_{1-z}), P(VF_{z}-HFP_{1-z}), P(VF_{z}-CDFE_{1-z}), P(VF_{z}-TrFE_{1-z}), and P(VF_{z}-TFE_{1-z}), the variable z is not limited but can range from _{z} of 0.7 to 1. Preferably, the fluoropolymer is a copolymer and has a dielectric constant higher than 8, measured at 1 kHz and 25° C. More preferably, the copolymer has an elastic modulus larger than 0.8 GPa at room temperature (20 to 25° C.).

In an embodiment of the present disclosure, the blend comprises a composition of the terpolymer and fluoropolymer where the fluoropolymer comprises up to about 15 weight percent (wt %) of the total weight of the two components. Additional polymers can be added to the blend. The blends can be prepared as films such as by co-extrusion, solution cast, spin cast or any method to produce a blend film of two or more polymers.

In one aspect of the disclosure, the transverse strain is the strain along the film surface. The polymer blend in the form of films can be used as just prepared, biaxially stretched, or uniaxially stretched.

Another aspect of the disclosure includes electromechanical devices comprising at least one layer of the polymer blend film. For example, an electromechanical device comprising multilayered polymer blend films such as the Braille display actuator is schematically illustrated in FIG. 4. The electromechanical devices can be part of fluid pumps (as the diaphragms and valves), as compact actuators for auto focusing of camera lenses, as actuators for micro-steering of minimumally invasive surgical devices such as graspers and EP catheters, etc.

Additional advantages of the present invention will become readily apparent to those skilled in this art from the following detailed description, wherein only the preferred embodiment of the invention is shown and described, simply by way of illustration of the best mode contemplated of carrying out the invention. As will be realized, the invention is capable of other and different embodiments, and its several details are capable of modifications in various obvious respects, all without departing from the invention. Accordingly, the drawings and description are to be regarded as illustrative in nature, and not as restrictive.

### BRIEF DESCRIPTION OF THE DRAWINGS

Reference is made to the attached drawings, wherein elements having the same reference numeral designations represent like elements throughout and wherein:

FIG. 1 is a graph of various strains generated in the polymer under electrical field, where S1 is the strain measured along the film stretching direction (the larger arrow indicates the film stretching direction); S2 is the strain measured transverse to the stretching direction; and S3 is the strain measured in the thickness direction and parallel to the applied electric field.

FIG. 2 is a graph of transverse strain S₁ as a function of applied electric field for a P(VDF-TrFE-CFE) (70/30/8 mol %) terpolymer.

FIG. 3 is a schematic of the semicrystalline polymer of PVDF based polymers.

FIG. 4 illustrates two examples of multilayered electromechanical devices that can be fabricated employing blend films in accordance with the present disclosure. Device (a) illustrates a multilayer lamination with an electrical connection and a device (b) illustrates a rolled multilayer device.

FIG. 5 is a graph comparing the transverse strain S₁ as a function of applied field for the uniaxially stretched blend films of P(VDF-TrFE-CFE) terpolymer (70/30/8 mol %) with P(VDF-CTFE) copolymer (91/9 mol %) at various weight percentages of P(VDF-CTFE) to the total weight of the blend, and the P(VDF-TrFE-CFE) terpolymer.

FIG. 6 is a graph comparing the elastic modulus of uniaxially stretched blend films as a function of temperature for blends of P(VDF-TrFE-CFE) terpolymer (70/30/8 mol %) with P(VDF-CTFE) copolymer (91/9 mol %) at various weight percentages (wt %) of P(VDF-CTFE) to the total weight of the blend, and neat films of the P(VDF-TrFE-CFE) and P(VDF-CTFE).

FIG. 7 is a graph comparing the electromechanical coupling factor k₃₁ at room temperature as a function of the electric field for blends of P(VDF-TrFE-CFE) terpolymer (70/30/8 mol %) with P(VDF-CTFE) copolymer (91/9 mol %) at 0 wt %, 2.5 wt %, 5 wt % and 10 wt % of the P(VDF-CTFE) copolymer to the total weight of the blend.

FIG. 8 is graph comparing the dielectric properties at 1 kHz as a function of temperature for blends of P(VDF-TrFE-CFE) terpolymer (70/30/8 mol %) with P(VDF-CTFE) copolymer (91/9 mol %) at various weight percentages of P(VDF-CTFE) to the total weight of the blend.

### DETAILED DESCRIPTION OF THE DISCLOSURE

The present disclosure is directed to polymer blends having improved electromechanical properties while also having improved mechanical properties, such as increased elastic modulus. For electromechanical applications, besides the strain level, a high elastic modulus is also highly desirable for polymer actuators among other components in devices.

However, when combining high strain terpolymers with other polymers which possess higher elastic modulus, it is possible and likely that the strain level will be reduced. This is because besides the elastic consideration, one major reason is the low dielectric constants of other insulation polymers. Terpolymers with high electrostrictive strain response (>3%) possess a high dielectric constant at room temperature (>40 at 1 kHz frequency), which is in fact the highest among insulation polymers with low dielectric loss (<10%) near room temperatures. The dielectric constants of other insulation polymers are mostly below 4 or even 3. Consequently, when these polymers are blended with the terpolymers, they will often reduce the real electrical field in the terpolymer region and reduce the strain under a fixed external electric field.

To overcome this problem, we investigated blends of P(VDF-TrFE-CFE) terpolymer with several fluoropolymers including P(VDF-CTFE) and P(VDF-HFP) (CTFE: chlorotrifluoropolymers; and HFP: hexafluoropropylene). These fluorocopolymers have dielectric constants higher than about 10 and also exhibit a high electric field induced polarization. As has been shown in earlier studies, the electrical field induced strain response originates from the electrical field induced molecular conformation change between the non-polar phase and polar phase in the terpolymer. Hence, it is believed that the strain response is from the crystalline region of the polymer. Further, P(VDF-TrFE-CFE) and other similar terpolymers are semicrystalline polymers (see FIG. 3). As a semicrystalline polymer, the elastic modulus of the amorphous phase/region of the polymer at temperatures above the glass transition temperature T_{g} is much lower than that of the crystalline phase. For the terpolymer P(VDF-TrFE-CFE), the glass transition temperature of the amorphous phase is −30° C. Therefore the overall elastic modulus of the terpolymers is much lower than that of the crystalline phase. However, it is believed that polymer modulus can be improved without materially affecting the electromechanical strain of the polymers if another polymer can provide a bridge between the crystallites of the terpolymer thereby strengthening the elastic modulus of the amorphous region. In this manner, the other polymers in the blends will not reduce the strain level in the crystalline phase but improve the elastic modulus of the overall polymers. In addition to increasing the elastic modulus of the system, use of added polymers to an electroactive fluoropolymer can improve the dielectric properties of the system as well.

In one embodiment of the present disclosure, a polymer blend comprises at least one electrostrictive terpolymer and at least one fluoropolymer. Advantageously the polymer blend has a transverse strain, i.e., a strain perpendicular to the applied electric field, that is about 1.5% or higher, e.g., a transverse strain of about 2%, 2.2%, 2.5%, 3% or higher (as measured at 100 MV/m). Further, the polymer blend also has an elastic modulus of no less than about 400 MPa, e.g. no less than about 450, 500, 550, or 600 MPa (as measured at 30° C. or lower, e.g. at about 25° C., 20° C., 15° C., or 10° C., and 1 Hz by dynamic mechanical analyzer). In one aspect of the disclosure, the polymer blend has a transverse strain that is 2% or higher, as measured at 100 MV/m, and an elastic modulus of no less than about 0.5 GPa, as measured at 25° C.

In an embodiment of the present disclosure, the polymer blend comprises a composition of the terpolymer and fluoropolymer where the fluoropolymer comprises up to about 15 wt %, e.g., up to about 10 wt % of the total weight of the two components. In one aspect of the present disclosure, the fluoropolymer comprises up to about 5 wt % of the total weight of the two components. Additional polymers can be added to the blends. The polymer blends can be prepared as films such as by co-extrusion, solution cast, spin cast, or any method to produce a blend film of two or more polymers.

The electrostrictive terpolymer can be selected from the group consisting of: polyvinylidene fluoride-trifluoroethylene-chlorofluoroethylene (P(VDF-TrFE-CFE)), polyvinylidene fluoride-trifluoroethylene-chlorodifluoroethylene (P(VDF-TrFE-CDFE)), polyvinylidene fluoride-trifluoroethylene-chlorotrifluoroethylene (P(VDF-TrFE-CTFE)), polyvinylidene fluoride-trifluoroethylene-hexafluoropropylene (P(VDF-TrFE-HFP)), polyvinylidene fluoride-trifluoroethylene-tetrafluoroethylene (P(VDF-TrFE-TFE)), polyvinylidene fluoride-tetrafluoroethylene-chlorofluoroethylene (P(VDF-TFE-CFE)), polyvinylidene fluoride-tetrafluoroethylene-chlorodifluoroethylene (P(VDF-TFE-CDFE)), polyvinylidene fluoride-tetrafluoroethylene-chlorotrifluoroethylene (P((VDF-TFE-CTFE)), polyvinylidene fluoride-tetrafluoroethylene-hexafluoropropylene (P(VDF-TFE-HFP)).

In one aspect of the present disclosure, the terpolymer can be expressed by the formula of P(VDFₓ-2nd monomer_{y}-3rd monomer_{1-x-y}), where the 2nd monomer is selected from TrFE, TFE, and the 3rd monomer is selected from CFE, CDFE, CTFE, HFP. The variables x and y are not limited but can be for x from about 0.50 to 0.75, e.g., about 0.55 to 0.70, and for y from about 0.2 to 0.4, e.g., about 0.25 to 0.35.

The fluoropolymer can be selected from the group consisting of P(VDF_{z}-CTFE_{1-z}), P(VDF_{z}-CFE_{1-z}), P(VDF_{z}-HFP_{1-z}), P(VDF_{z}-CDFE_{1-z}), P(VDF_{z}-TrFE_{1-z}), P(VDF_{z}-TFE_{1-z}), P(VF_{z}-CTFE_{1-z}), P(VF_{z}-CFE_{1-z}), P(VF_{z}-HFP_{1-z}), P(VF_{z}-CDFE_{1-z}), P(VF_{z}-TrFE_{1-z}), and P(VF_{z}-TFE_{1-z}), the variable z is not limited but can range from about 0.7 to 1, e.g., about 0.85 to 0.99. Preferably, the fluoropolymer has a dielectric constant higher than 8, measured at 1 kHz and 25° C. More preferably, the fluoropolymer has an elastic modulus larger than about 0.8 GPa at room temperature (20 to 25° C.).

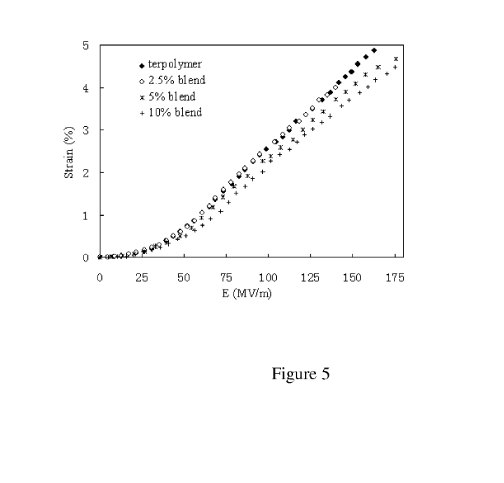

As presented in FIG. 5, which is the transverse strain measured at room temperature as a function of applied field for the blends of P(VDF-TrFE-CFE) terpolymer (70/30/8 mol % composition) with a P(VDF-CTFE) copolymer 91/9 mol % at different wt % of P(VDF-CTFE) to the total weight of the blend. As can be seen, there is very little reduction in the strain response of blends with 5 wt % of P(VDF-CTFE). Table I summarizes these results (at different electric fields):

TABLE I
Transverse strain for terpolymer blends at different electric fields
140 MV/m

| Material: | Terpolymer | 2.5 wt % blend | 5 wt % blend | 10 wt % blend |
|---|---|---|---|---|
| Strain | 4.02% | 4.00% | 3.72% | 3.46% |

100 MV/m

| | | | | |
|---|---|---|---|---|
| Material: | Terpolymer | 2.5 wt % blend | 5 wt % blend | 10 wt % blend |
| Strain | 2.57% | 2.60% | 2.34% | 2.20% |

50 MV/m

| | | | | |
|---|---|---|---|---|
| Material: | Terpolymer | 2.5 wt % blend | 5 wt % blend | 10 wt % blend |
| Strain | 0.68% | 0.66% | 0.57% | 0.48% |

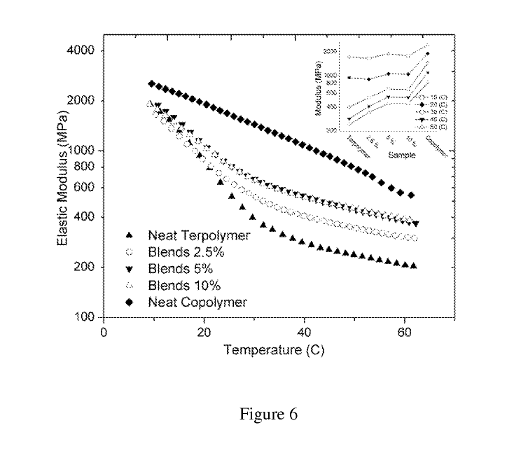

On the other hand, the elastic modulus Y of the blends is increased as the P(VDF-CTFE) wt % increases (see FIG. 6), especially at temperatures above room temperature. The elastic modulus was measured along the film stretching direction from the uniaxially stretched blend films (with the stretching ratio higher than five times). Therefore, the blends exhibit higher elastic energy density, as defined Uₘ=½ YS², where S is the strain, and better electromechanical response. FIG. 6 shows the relationship of blends of P(VDF-TrFE-CFE) with different wt % of P(VDF-CTFE). The blends comprise up to about 10 wt % of P(VDF-CTFE) and the elastic modulus was measured at temperatures ranging from about 10° C. to about 60° C.

In an embodiment of the present disclosure, the blend comprises a composition of the terpolymer to fluoropolymer where the fluoropolymer comprises up to about 15 wt %, e.g., up to about 10 wt % of the total weight of the two components. In one aspect of the present disclosure, the ratio of terpolymer to fluoropolymer can be expressed as terpolymer_{1-b}/fluoropolymer_{b}, where b is in the range of about 15 wt % to about 0.5 wt %, preferably between about 5 wt % and about 1 wt %, and more preferably between about 5 wt % and 2.5 wt %. The elastic modulus of the blend can be higher than about 400 MPa as measured at about 30° C. or lower, e.g. at about 25° C., 20° C., 15° C., or 10° C. Additional polymers can be added to the blend. The blends can be prepared in the form of films such as by co-extrusion, solution cast, spin cast, or any method to produce a blend film of two or more polymers. As films, the polymer blends can be used in actuators such for cameras, and cell phones in place of the materials typically used for such devices.

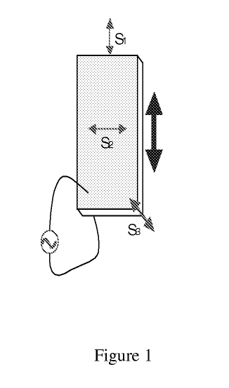

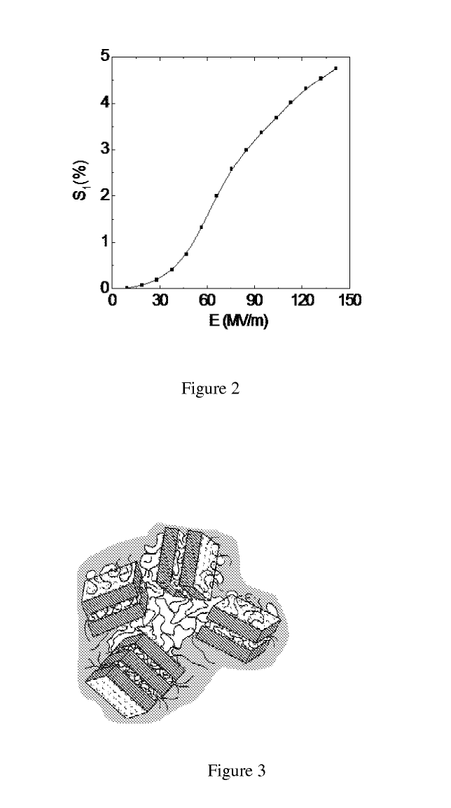

In another aspect of the disclosure, the transverse strain is the strain along the film surface (in the direction perpendicular to the applied field such as S₁ in FIG. 1). The polymer blend in the form of films can be used as just prepared, biaxially stretched, or uniaxially stretched. The transverse strain along the film drawing direction of uniaxially stretched blend films with the drawing ratio of more than 5 times is 2% or higher under a 100 MV/m electrical field. Advantageously the blend film can be stretched uniaxially to at least four times of its original length and stretched biaxially at least twice along the two lateral directions of its original length. The elastic modulus of uniaxially stretched blend films with the drawing ratio of more than 4 times along the film drawing direction can be higher than 0.6 GPa, measured at room temperature and 1 Hz, and higher than 0.4 GPa at 40° C. and 1 Hz.

In one embodiment of the present disclosure, the polymer blend is in the form of a film which is uniaxially stretched and has a drawing ratio of more than 2 times along the film drawing direction. Preferably the film has a transverse strain of 1.5% or higher under a 100 MV/m electrical field and an elastic modulus higher than 0.5 GPa, measured at room temperature and 1 Hz, or an elastic modulus higher than 0.4 GPa, measured at 40° C. and 1 Hz.

For actuator and electromechanical transducer materials, the elastic energy density Uₘ=YS²/2, where Y is the elastic modulus and S is the strain, is another important parameter. Although the blends may not improve the energy density at room temperature, (Uₘ is 0.71 J/cm³ for the transverse strain S₁ of the neat P(VDF-TrFE-CFE) terpolymer of 70/30/8 mol %, and is 0.71 J/cm³, 0.73 J/cm³, and 0.62 J/cm³ for the blends with about 2.5 wt %, 5 wt % and 10 wt % of P(VDF-CTFE) 91/9 mol % copolymer), the blends increase the elastic energy density at higher temperatures. For example, for the transverse strain S₁ at 40° C. and under 140 MV/m Uᵣ for the neat terpolymer is 0.226 J/cm³ while for the blend films with 2.5 wt % and 5 wt % and 10 wt % P(VDF-CTFE), U is increased to 0.33 J/cm³ and 0.37 J/cm³ and 0.323 J/cm³ at 40° C. and 140 MV/m.

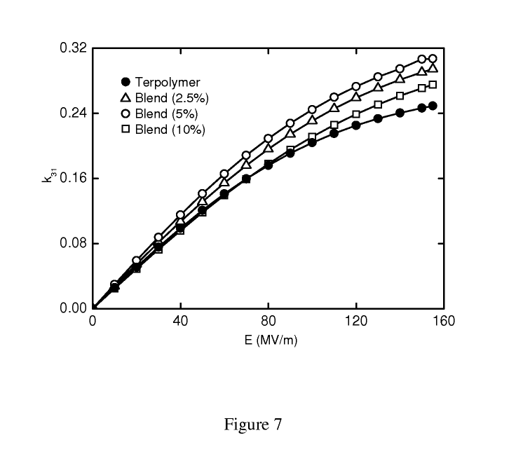

In electromechanical applications, the electromechanical coupling factor k₃₁ measures the energy conversion efficiency in converting electric energy and mechanical energy. For electrostrictive materials, the electromechanical coupling factor can be expressed as

$${k}_{31}^{2} = \frac{{kS}_{1}^{2}}{s [ P ln ( \frac{{P}_{s} + P}{{P}_{s} - P} ) + {P}_{s} ln ( 1 - {( \frac{P}{{P}_{s}} )}^{2} ) ]}$$

where s is the elastic compliance (s=1/Y, Y elastic modulus) and Pₛ is the saturation polarization. In ferroelectric based electrostrictive materials such as the terpolymer blends, the dependence of P on applied electric fields E can be approximated by P=Pₛ tan h(kE), where k is a constant. By fitting the experimental P-E curves of the blends with this equation, Pₛ and k can be obtained. For the blends with 0, 2.5%, 5% copolymer, Pₛ is 93, 104, 97 mC/m², and k is 8.1, 6.9, 7.3×10⁻⁹ m/V, respectively. The electromechanical coupling factor k₃₁ thus obtained for the blends is presented in FIG. 7. The increase of the copolymer, which results in an increase in the elastic modulus in the blends, raises k₃₁ until about 5%, and beyond that, k₃₁ decreases with the copolymer increase in the blends, which is caused by the decrease of the strain for the blends with higher P(VDF-CTFE) content. For instance, k₃₁ is 0.25, 0.29, 0.31 for the blends with 0, 2.5%, 5% copolymer at 150 MV/m, respectively.

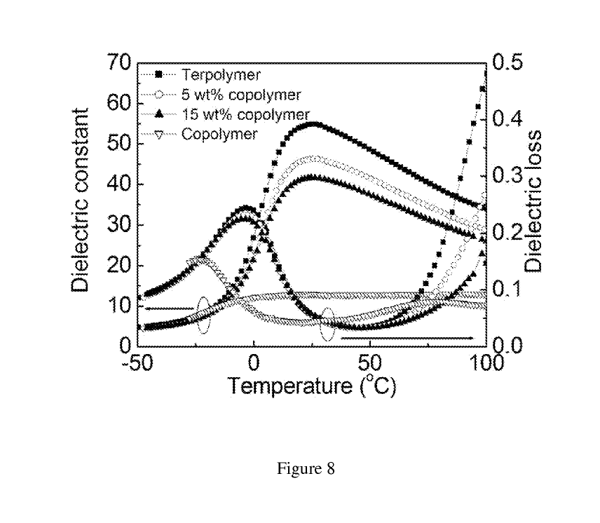

FIG. 8 is a graph comparing the dielectric properties at 1 kHz as a function of temperature for blends of P(VDF-TrFE-CFE) terpolymer (70/30/8 mol %) with P(VDF-CTFE) copolymer (91/9 mol %) at various weight percentages of P(VDF-CTFE) to the total weight of the blend. The blend with 5 wt % P(VDF-CTFE) has dielectric constant around 45 at 1 kHz and 25° C. Although it is slightly lower than the pure P(VDF-TrFE-CFE) dielectric constant of around 55 at the same condition, it is still significantly higher than other polymers with dielectric constants below 5. The high dielectric constant of the blend partially contributes to the high electromechanical response under electric field.

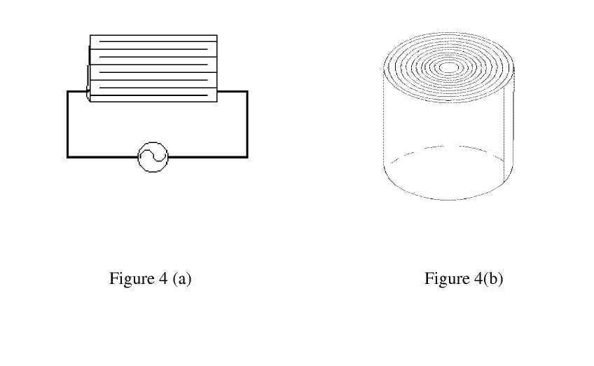

Another aspect of the disclosure includes electromechanical devices comprising at least one layer of the polymer blend film. For example, an electromechanical device comprising multilayered polymer blend films is schematically illustrated in FIG. 4. This figure shows the polymer blends in the form of multilayer sheets either in a lamination configuration or a rolled multilayer device. The electromechanical devices can be part of fluid pumps (as the diaphragms and valves), as compact actuators for auto focusing of camera lenses, as actuators for micro-steering of minimumally invasive surgical devices such as graspers and EP catheters, etc. The blends can improve electromechanical devices in the following aspects: actuator dimensions can be decreased due to increased elastic energy density; the increased modulus can lead to enhanced device reliability and alleviated electrode clamping effect; efficiency of devices can be increased due to increased electromechanical coupling factor in some of the blends.

Only the preferred embodiment of the present invention and examples of its versatility are shown and described in the present disclosure. It is to be understood that the present invention is capable of use in various other combinations and environments and is capable of changes or modifications within the scope of the inventive concept as expressed herein. Thus, for example, those skilled in the art will recognize, or be able to ascertain, using no more than routine experimentation, numerous equivalents to the specific substances, procedures and arrangements described herein. Such equivalents are considered to be within the scope of this invention, and are covered by the following claims.

1-16. (canceled)

17. An electromechanical device which comprises at least one layer of a polymer blend which comprises: (i) at least one electrostrictive poly(vinylidene fluoride) (PVDF) based terpolymer, and (ii) at least one fluoropolymer;
wherein the least one layer of the polymer blend is configured to convert electrical energy into mechanical energy and/or to convert mechanical energy into electrical energy in the device.

18. The electromechanical device of claim 17 wherein the device includes an electromechanical actuator comprising the at least one layer of the electrostrictive polymer and the device is selected from the group of devices consisting of fluid pumps, cameras, surgical devices, and EP catheters.

19. An actuator for a device comprising at least one layer of a polymer blend which comprises: (i) at least one electrostrictive poly(vinylidene fluoride) (PVDF) based terpolymer, and (ii) at least one fluoropolymer.

20. The electromechanical device of claim 17, wherein the polymer blend is in the form of multilayer sheets.

21. The electromechanical device of claim 20, wherein the multilayer sheets are arranged in a laminate configuration.

22. The electromechanical device of claim 20, wherein the multilayer sheets are arranged in a roll configuration.

23. The electromechanical device of claim 17, wherein the layer has a transverse strain that is 1.5% or higher, as measured at 100 MV/m, and an elastic modulus of no less than about 0.4 GPa, as measured at 30° C.

24. The electromechanical device of claim 17, wherein the layer has a transverse strain that is 2.5% or higher, as measured at 100 MV/m, and an elastic modulus of no less than about 500 MPa, as measured at 30° C.

25. The electromechanical device of claim 17, wherein said terpolymer is selected from the group consisting of: polyvinylidene fluoride-trifluoroethylene-chlorofluoroethylene (P(VDF-TrFE-CFE)), polyvinylidene fluoride-trifluoroethylene-chlorodifluoroethylene (P(VDF-TrFE-CDFE)), polyvinylidene fluoride-trifluoroethylene-chlorotrifluoroethylene (P(VDF-TrFE-CTFE)), polyvinylidene fluoride-trifluoroethylene-hexafluoropropylene (P(VDF-TrFE-HFP), polyvinylidene fluoride-trifluoroethylene-tetrafluoroethylene (PVDF-TrFE-TFE), polyvinylidene fluoride-tetrafluorethylene-chlorofluoroethylene (P(VDF-TFE-CFE), polyvinylidene fluoride-tetrafluoroethylene-chlorodifluoroethylene (P(VDF-TFE-CDFE)), polyvinylidene fluoride-tetrafluoroethylene-chlorotrifluoroethylene (P(VDF-TFE-CTFE), and polyvinylidene fluoride-tetrafluorethylene-hexafluoropropylene (P(VDF-TFE-HFP).

26. The electromechanical device of claim 17, wherein the chemical formula of the terpolymer is P(VDFₓ-2nd monomer_{y}-3rd monomer_{1-x-y}), wherein x is from 0.5 to 0.75, and y is from 0.2 to 0.4, and wherein the 2nd monomer is TrFE or TFE, and the 3rd monomer is CFE, CDFE, CTFE, or HFP.

27. The electromechanical device of claim 26, wherein x is from 0.55 to 0.70 and y is from 0.25 to 0.35.

28. The electromechanical device of claim 17, wherein the fluoropolymer is selected from the group consisting of: P(VDF_{z}-CTFE_{1-z}), P(VDF_{z}-CFE_{1-z}), P(VDF_{z}-HFP_{1-z}), P(VDF_{z}-CDFE_{1-z}), P(VDF_{z}-TrFE_{1-z}), P(VDF_{z}-TFE_{1-z}), P(VF_{z}-CTFE_{1-z}), P(VF_{z}-CFE_{1-z}), P(VF_{z}-HFP_{1-z}), P(VF_{z}-CDFE_{1-z}), P(VF_{z}-TrFE_{1-z}), and P(VF_{z}-TFE_{1-z}); wherein z is in the range of 0.7 to 1.

29. The electromechanical device of claim 28, wherein z is in the range of 0.85 to 0.99.

30. The electromechanical device of claim 17, wherein the at least one layer is in the form of a uniaxially or biaxially stretched film.

31. The electromechanical device of claim 30, wherein the film is uniaxially stretched and has a drawing ratio of more than 2 times along the film drawing direction.

32. The electromechanical device of claim 30, wherein the film is stretched biaxially at least two times along the two lateral directions of its original length.

33. The electromechanical device of claim 17, wherein the fluoropolymer is included in the polymer blend between 15 wt % to 0.5 wt % based on the total weight of the terpolymer and fluoropolymer in the polymer blend.

34. The electromechanical device of claim 17, wherein the fluoropolymer is included in the polymer blend between 10 wt % to 5 wt % based on the total weight of the terpolymer and fluoropolymer in the polymer blend.

35. The actuator of claim 19, wherein the polymer blend is in the form of multilayer sheets.

36. An electromechanical device comprising an actuator which includes one or more layers of a polymer blend for the operation of the actuator;
wherein the polymer blend comprises: (i) at least one electrostrictive poly(vinylidene fluoride) (PVDF) based terpolymer, and (ii) at least one fluoropolymer; and
wherein the one or more layers has a transverse strain that is 1.5% or higher, as measured at 100 MV/m, and an elastic modulus of no less than about 0.4 GPa, as measured at 30° C.
